(19) United States
(12) Patent Application Publication
(10) Pub. No.: US 2019/0357379 A1
(43) Pub. Date: Nov. 21, 2019

(54) Two-Phase Immersion Cooling System and Method with Enhanced Circulation of Vapor Flow Through a Condenser

(71) Applicant: TAS Energy Inc., Houston, TX (US)

(72) Inventor: Jack Kolar, Houston, TX (US)

(21) Appl. No.: 16/019,252

(22) Filed: Jun. 26, 2018

Related U.S. Application Data
(63) Continuation-in-part of application No. 15/983,739, filed on May 18, 2018.

(51) Int. Cl. H05K 7/20

(52) U.S. Cl. CPC H05K 7/203; H05K 7/20818

(57) ABSTRACT

An immersion tank for a two-phase immersion cooling system holds a bath of dielectric heat transfer fluid in liquid phase in a container provided within an outer wall forming the immersion tank. The dielectric heat transfer fluid in liquid phase is in equilibrium with the fluid vapor phase. The boiling point of the dielectric heat transfer fluid is adjusted by changing the pressure within the immersion tank, to maintain a target operating temperature of the electronic components within the bath.

### CROSS-REFERENCE TO RELATED APPLICATIONS

This application is a Continuation-In-Part of U.S. patent application Ser. No. 15/983,739, filed on May 18, 2018, and entitled “TWO-PHASE IMMERSION COOLING SYSTEM AND METHOD WITH ENHANCED CIRCULATION OF VAPOR FLOW THROUGH A CONDENSER,” which is included herein by reference.

### BACKGROUND

This disclosure generally relates to methods and apparatus for cooling electric or electronic components using one or more dielectric heat transfer fluids and, more specifically, to methods and apparatus for maintaining a target temperature by varying the pressure inside of a sealed tank containing the components and the dielectric heat transfer fluid.

Conventional electronic components are designed to operate over a specified temperature range with upper limits generally below 70 deg. C for commercial grade, 85 deg. C for industrial grade, or 125 deg. C for military grade; therefore, these components may require cooling such that their internal temperature remains below these upper limits. The cooling can be performed, among other ways, by the vaporization of a dielectric heat transfer fluid, such as perfluorocarbons, fluoroketones, or hydrofluoroethers. Depending on its composition, the dielectric heat transfer fluid may have a boiling temperature at atmospheric pressure that may range from approximately 35 deg. C to approximately 100 deg. C, such that the boiling temperature at atmospheric pressure is lower than the upper limits at which conventional electronic components are designed to operate. The electronic components are immersed in the dielectric heat transfer fluid in liquid phase. When the surfaces of electronic components in contact with the dielectric heat transfer fluid reach the boiling temperature of the dielectric heat transfer fluid, the dielectric heat transfer fluid located nearby will vaporize, therefore absorbing heat from the electronic components.

For example, in a known two-phase immersion cooling system illustrated in FIGS. 1, 2 and 3, electronic components can be placed near a bottom of a metallic tank 10 which may be thermally and electrically insulated with a skin 12. The metallic tank 10 is filled with a dielectric fluid in liquid phase 14. The dielectric fluid in liquid phase 14 can be in direct thermal contact with the electronic components. In use, the electronic components generate heat. The heat is absorbed by the vaporization of the dielectric fluid. The dielectric fluid in vapor phase 16, having a density much lower than the dielectric fluid in liquid phase 14, rapidly bubbles up above the surface of the liquid (i.e., the top surface of the dielectric fluid in liquid phase 14). Condensers 18 (e.g., coils in which water at a temperature at least 15 deg. C below the boiling temperature of the dielectric fluid) are placed within the walls of the metallic tank 10. The dielectric fluid in vapor phase 16 flows through the condenser 18 in a generally upward direction. Upon contact with the condensers 18, the dielectric fluid in vapor phase 16 releases heat to the condensers 18 (e.g., increases the temperature of the water circulating in the coils) and returns in liquid phase. The dielectric fluid in liquid phase 14, having a density much higher than the dielectric fluid in vapor phase 16, rapidly drips down toward the bottom of the metallic tank 10. The cycle consisting of the liquid in contact with the electronic components vaporizing, the vapor rising above the liquid, the vapor in contact with the condensers 18 turning into liquid, and the liquid falling through the vapor, allows the transfer of the heat generated by the electronic components to the condenser.

Examples of known condensers include, for small systems (a few kW), radiator-like structures with appropriate fin stock. However, for larger systems, the accepted wisdom in the art is that the condenser 18 should be fabricated as banks of enhanced tubes 50 of a type similar to that used in industrial water-cooled chiller condensers. The enhanced efficiency of the tube surfaces enables the condensation of the dielectric fluid in vapor phase 16 in a very limited space on top of the metallic tank 10.

To minimize losses of the dielectric fluid during use of this known two-phase immersion cooling system, the metallic tank 10 is preferably provided with a freeboard space 46 having a height of at least 10 cm above the condensers 18, so that the vapor surface (i.e., the top surface of the dielectric fluid in vapor phase 16) does not reach the top of the metallic tank 10. Further, the top of the metallic tank 10 is sealed by a lid 24 and/or accessory plate 26, which are made of metal or glass, and O-rings or gaskets 22, which are made of elastomers. The accessory plate 26 includes perforations to accommodate, for example, a conduit 28 to provide electrical power to, or signals to or from the electronic components, venting and pressure control means 42, and signals from monitoring means 30 (e.g., temperature sensors and/or float switches). The perforations in the accessory plate 26 are preferably located above the surface of the liquid, and more preferably above the surface of the vapor. The conduit 28 can be potted with resin, and/or have a termination immersed in the liquid phase 14 rather than in the vapor phase 16, because the liquid phase 14 is more viscous than the vapor phase 16, thus the liquid phase 14 is less prone to migration in the interstices between the wires disposed in the conduit 28 than the vapor phase 16. Still further, a secondary condenser 32 may be provided in the venting and pressure control means 42 to condense and retain much of the dielectric fluid in vapor phase 16 that could otherwise be entrained with air vented out of the metallic tank 10.

Moisture in the metallic tank 10 can be managed using a desiccant 44 located in the freeboard space 46. Hydrocarbon oils impurities can be managed using a carbon cartridge, filter and pump assembly 48, located in the liquid phase 14 of the dielectric fluid.

The metallic tank 10 can be operated at atmospheric pressure using the venting and pressure control means 42. Small variations of volume in the metallic tank 10 can be accommodated with the expansion and contraction of bellows 36. Large increases of volume in the metallic tank 10, for example, caused by degassing of the dielectric fluid in liquid phase 14, or the rise of the surface of the vapor, can be accommodated by opening a solenoid valve 42 triggered by the bellows 36 actuating a switch 38 upon reaching a fully expanded position. Large decreases of volume in the metallic tank 10, for example, caused by a drop of the surface of the vapor, can be accommodated by opening the solenoid valve 42 triggered by a vacuum switch 34.

Other known two-phase cooling systems are described in U.S. Pat. Appl. Pub. No. 2014/0218858.

When the immersion tank is not sealed, the pressure in the immersion tank stays at the atmospheric pressure, the boiling point of a particular fluid stays at the normal atmospheric boiling point, and the liquid bath can essentially be operated only at the fixed discrete temperature of the atmospheric boiling point of one particular fluid. The dielectric heat transfer fluids presently known have specific boiling point temperatures that are fixed at atmospheric pressure. There may be a relatively wide temperature gap between the boiling point of a dielectric heat transfer fluid and the next available boiling point of another dielectric heat transfer fluid. For instance, the boiling point of a commercially available dielectric fluid, 3M™ Novec™ 7200 Engineered Fluid, has a boiling point of about 76° C. at atmospheric pressure. Another commercially available dielectric fluid, 3M™ Novec™ 7100 Engineered Fluid, has a boiling point of about 61° C. at atmospheric pressure. In some cases, the electric or electronic components should ideally be immersed in a liquid bath at a temperature that falls within the temperature gap between the boiling point of a dielectric heat transfer fluid and the next available boiling point of another dielectric heat transfer fluid. For example, if it is desired that the electric or electronic components be immersed in a liquid bath at a temperature of 69° C. for optimized operation of the electric or electronic components, neither 3M™ Novec™ 7200 Engineered Fluid nor 3M™ Novec™ 7100 is ideal for providing such liquid bath, as 3M™ Novec™ 7100 Engineered Fluid has too low a boiling point and 3M™ Novec™ 7200 Engineered Fluid has too high a boiling point.

With the advancement of High-Performance Computing, where the temperature of electric or electronics components is preferably precisely controlled to maximize efficiency for simulation or encryption computing, there is a continuing need in the art to control temperature in two-phase immersion cooling. Thus, there is a continuing need in the art for improved two-phase immersion cooling systems and methods.

### BRIEF SUMMARY OF THE DISCLOSURE

The disclosure describes a two-phase immersion cooling system.

The two-phase immersion cooling system may comprise an immersion tank, which may include a container for holding a bath of dielectric heat transfer fluid in liquid phase and at least one condenser for condensing dielectric heat transfer fluid from a vapor phase to a liquid phase.

The two-phase immersion cooling system may comprise an electric component having a temperature sensor. An actual temperature inside the immersion tank may be measured by the temperature sensor, or an equivalent sensor.

In some embodiments, the two-phase immersion cooling system may comprise a means of selectively adjusting a pressure inside the immersion tank. The means of selectively adjusting the pressure inside the immersion tank may comprise a vacuum pump to reduce the pressure below atmospheric pressure and/or a compressor to increase the pressure above atmospheric pressure. For example, the two-phase immersion cooling system may comprise a vacuum pump located external to the immersion tank and configured to reduce a pressure inside the immersion tank below atmospheric pressure.

The two-phase immersion cooling system may comprise an external storage tank. In some embodiments, the means of selectively adjusting the pressure inside the immersion tank may be connected between the immersion tank and the external storage tank.

The two-phase immersion cooling system may comprise means for liquefying dielectric heat transfer fluid in vapor phase, which may be contained in the external storage tank, and means for pumping into the immersion tank dielectric heat transfer fluid in liquid phase, which may be contained in the external storage tank. For example, the two-phase immersion cooling system may comprise a secondary condenser. A vacuum pump exhaust may be connected to the secondary condenser. The secondary condenser may be connected to an inlet of the external storage tank. Further, an outlet of the external storage tank may also be connected to the immersion tank.

A fluid may be circulating through the at least one condenser. The fluid may be water or essentially water. The two-phase immersion cooling system may comprise a valve configured to vary a flow rate of the fluid circulating through the at least one condenser and/or a cooling system configured to vary a temperature of the fluid circulating through the at least one condenser.

The two-phase immersion cooling system may comprise an automation system. In some embodiments, the automation system may be programmed to adjust the pressure inside the immersion tank based upon the actual temperature measured inside the immersion tank and a target temperature. In some embodiments, the automation system may be programmed to actuate the valve configured to vary the flow rate of the fluid circulating through the at least one condenser. The flow rate may be varied based on the actual temperature measured inside the immersion tank and the target temperature. In some embodiments, the automation system may be programmed to control the cooling system configured to vary the temperature of the fluid circulating through the at least one condenser. The cooling system may be controlled based on the actual temperature measured inside the immersion tank and the target temperature.

### BRIEF DESCRIPTION OF THE DRAWINGS

For a more detailed description of the embodiments of the disclosure, reference will now be made to the accompanying drawings, wherein:

FIG. 1 is an exploded view of a known two-phase immersion cooling system;

FIG. 2 is a perspective view of a known condenser for use in a two-phase immersion cooling system;

FIG. 3 is a sectional view of a known two-phase immersion cooling system;

FIG. 4 is a perspective view of an immersion tank suitable for use in a two-phase immersion cooling system in accordance with an embodiment;

FIG. 5 is a side view of the immersion tank shown in FIG. 4;

FIG. 5A is a schematic of a portion of the immersion tank shown in FIG. 4;

FIG. 6 is a top view of the immersion tank shown in FIG. 4;

FIG. 7 is a perspective view of a condenser in accordance with an embodiment;

FIG. 8 is a perspective view of a first end portion of the condenser shown in FIG. 7; and

FIG. 9 is a perspective view of a second end portion of the condenser shown in FIG. 7;

FIG. 10 is a schematic of a two-phase immersion cooling system with variable vapor temperature and pressure control; and

FIG. 11 is a Process Flow Chart for operation of the two-phase immersion cooling system shown in FIG. 10.

### DETAILED DESCRIPTION

It is to be understood that the following disclosure describes several exemplary embodiments for implementing different features, structures, or functions of the invention. Exemplary embodiments of components, arrangements, and configurations are described below to simplify the disclosure; however, these exemplary embodiments are provided merely as examples and are not intended to limit the scope of the invention. Additionally, the disclosure may repeat reference numerals and/or letters in the various exemplary embodiments and across the Figures provided herein. This repetition is for the purpose of simplicity and clarity and does not in itself dictate a relationship between the various exemplary embodiments and/or configurations discussed in the various Figures. Finally, the exemplary embodiments presented below may be combined in any combination of ways, i.e., any element from one exemplary embodiment may be used in any other exemplary embodiment, without departing from the scope of the disclosure.

All numerical values in this disclosure are approximate values unless otherwise specifically stated. Accordingly, various embodiments of the disclosure may deviate from the numbers, values, and ranges disclosed herein without departing from the intended scope. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact.

As one having ordinary skill in the art will appreciate, various entities may refer to the same elements by different names, and as such, the naming convention for the elements described herein is not intended to limit the scope of the invention, unless otherwise specifically defined herein. Further, the naming convention used herein is not intended to distinguish between components that differ in name but not function.

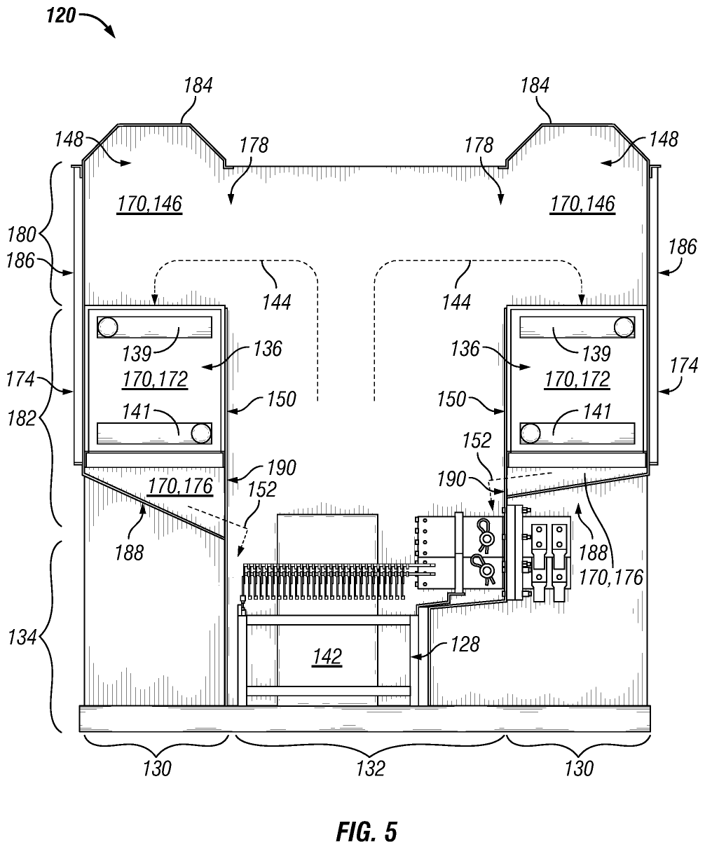

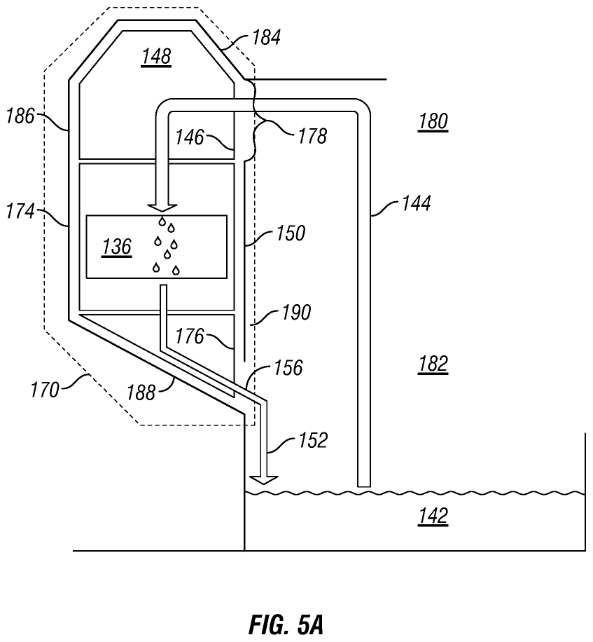

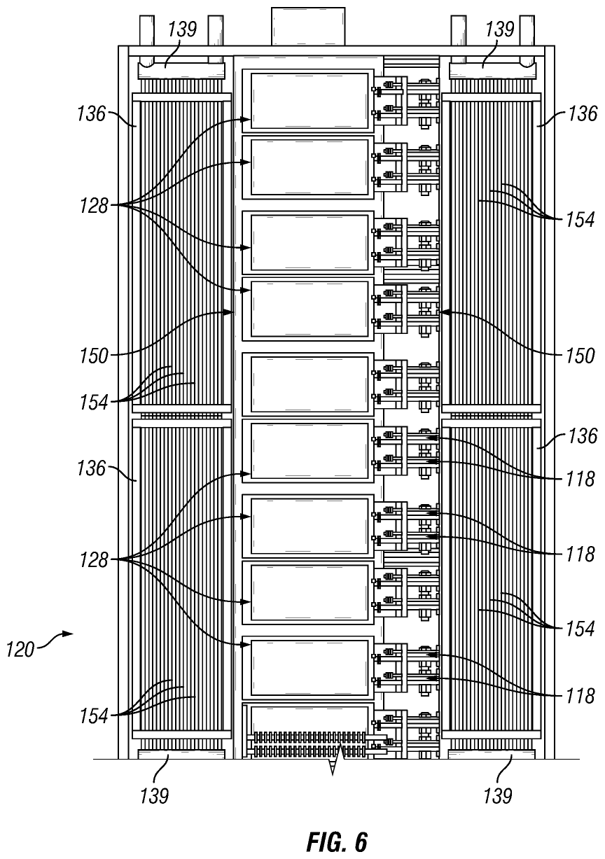

Referring to FIGS. 4, 5 and 6, an example embodiment of an immersion tank 120 implementing a two-phase immersion cooling system is illustrated. One or more immersion tank can be collocated into a unit or data center. The immersion tank 120 is preferably but not necessarily a sealed vessel. The immersion tank 120 has, in the lateral direction, a central zone 132 and distal zones 130, each of the distal zones 130 being located on the side of the central zone 132. Electric or electronic components to be cooled may be assembled on one or more electronic component board 160. The one or more electronic component board 160 can be disposed essentially vertically in modular case 128. The modular case 128 can be immersed, preferably entirely immersed, into a container 142 holding a bath of dielectric heat transfer fluid in liquid phase. A circulating fluid, typically but not exclusively water, is passed through one or more condenser 136. In the foregoing, phase transitions (liquid to vapor and vapor to liquid) and convection of the dielectric heat transfer fluid occurring in the immersion tank 120 are used to absorb the heat generated by the electric or electronic components and to release the heat to the circulating fluid. Thus, the electric or electronic components are cooled while the circulating fluid is warmed.

In the example embodiment shown in FIGS. 4, 5, 5A, and 6, the container 142 used for holding the bath of dielectric heat transfer fluid in liquid phase is located in a lower space 134 of immersion tank 120. Each of the one or more condenser 136 is located in any of the distal zones 130, above the top level of the bath of dielectric heat transfer fluid in liquid phase.

In other embodiments, the relative positions of the condenser and the bath of dielectric heat transfer fluid in liquid phase can be switched, such that a bath of dielectric heat transfer fluid in liquid phase may be located in each of the distal zones of the immersion tank, and the condenser may be located in the central zone of the immersion tank, above the top level of the bath of dielectric heat transfer fluid in liquid phase.

Without being limited by any working principle, a circulation flow pattern configuration may advantageously be utilized to draft the vapor of dielectric fluid bubbling out of the bath of dielectric heat transfer fluid into the condenser 136 and to generate a circulation pattern 144 of the dielectric heat transfer fluid in vapor phase, therefore increasing the efficiency of the condenser 136. Indeed, the vapor condensation may create a low-pressure zone that drafts the vapor toward the entire upper surface at the top of the condenser 136. The pressure at the top of condenser 136 may be lower than the pressure of vapor phase at the top surface of the dielectric fluid in liquid phase. This lower pressure may tend to draft the vapor phase within the central zone 132, through the middle space 182, and toward the upper space 180, and to promote the deflection of the flow of vapor phase within the upper space 180, toward the distal zone 130 and the top of the condenser 136. In addition, the progressive condensing of the vapor phase into a liquid phase within condenser 136 may further cause a slight pressure decrease between the top and the bottom of condenser 136. This slight pressure decrease may further draw down the vapor phase through the condenser 136, initiate and accelerate the circulation pattern 144. For example, gravity causes the liquid phase generated by the condensation of the vapor phase to drain downwards within the condenser 136. The draining of the liquid phase may create a siphon-like action which further lowers the pressure and promotes draw down of the vapor phase through the condenser 136. Thus, the vapor phase and the liquid phase flow in a downward direction through the condenser 136.

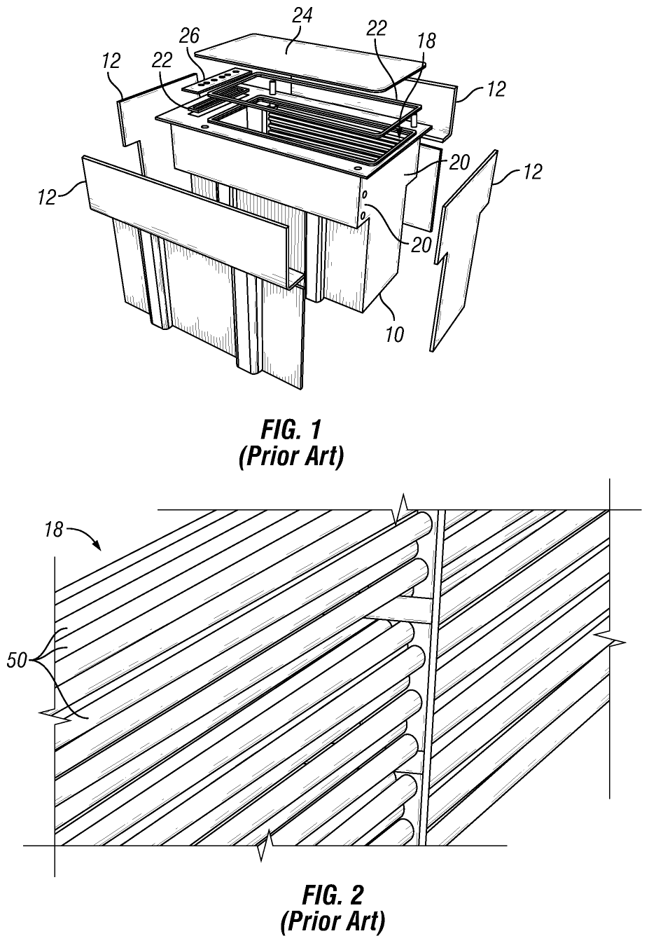

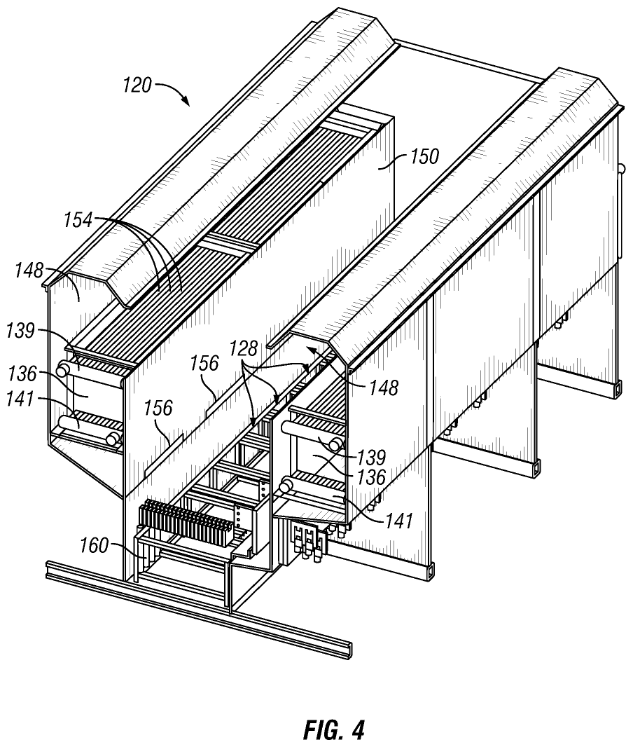

For example, the circulation pattern 144 configuration may be efficiently obtained when the condenser 136 snuggly fits in a vertical portion of a channel 170. As used herein, a channel refers to a structure that encloses a passage between at least two disjoint apertures, wherein one of the two disjoint apertures may form an inlet and the other of the two disjoint apertures may form an outlet. The channel 170 may be formed by a combination of portions of the walls of the immersion tank 120, and divider plates. The channel 170 is configured to guide the flow of the dielectric fluid in vapor phase through the condenser 136 in a generally downward direction. The flow direction of the vapor phase through the condenser 136 of the immersion tank 120 is thus opposite from the flow direction of the vapor phase through the condenser 18 of the known two-phase immersion cooling system illustrated in FIGS. 1, 2 and 3, where the flow of vapor phase is in a generally upward direction, and opposite to the flow of the liquid phase. In other words, in the embodiment shown in FIGS. 4, 5, 5A, and 6, the vapor phase first circulates upwards in the central zone 130, then the flow of vapor phase is deviated in the upper space 180 until the vapor phase circulates downwards to enter the condenser 136 from the top of the condenser. Finally, the vapor phase circulates downwards through the condenser 136 in the distal zone 130. In contrast, in the known two-phase immersion cooling system illustrated in FIGS. 1, 2 and 3, the vapor phase directly enters the condenser 18 from the bottom of the condenser with relatively minimal turning of the vapor.

In the example embodiment shown in FIGS. 4, 5, 5A, and 6, the channel 170 has an inlet 178 open to an upper space 180 of the immersion tank 120. The channel 170 comprises a vapor duct 146, a vertical portion or shaft portion 172, and a liquid funnel 176. The vapor duct 146 is located vertically above the condenser 136. The shaft portion 172 is formed by one or more divider plate 150 and a vertical lateral portion 174 of the outer wall of the immersion tank 120. The liquid funnel 176 is located vertically below the condenser 136. The channel 170 has an outlet open to a middle space 182 of the immersion tank 120, for example above the top level of the bath of dielectric heat transfer fluid. The outlet may be formed by one or more openings 156 included in the divider plate 150.

In other embodiments where the bath of dielectric heat transfer fluid in liquid phase is located in one or more distal zones of the immersion tank, a channel inlet may be open to an upper space of one of the distal zones (above one of the baths), and a channel outlet may be open to a middle space of the immersion tank.

In the example embodiment shown in FIGS. 4, 5, 5A, and 6, the container 142 used for holding the bath of dielectric heat transfer fluid in liquid phase, while located in the central zone 132, is not located exactly in the center of the immersion tank 120. The condenser 136 located in a distal zone 130 can be identical to a condenser 136 located in another distal zone 130, but the rates at which circulating fluid is passed through the coils of the condensers located on both sides preferably differ from each other to compensate for the dissymmetry. Alternatively, the condenser 136 located in one distal zone 130 may have different size coils from the condenser 136 located in another distal zone 130 to compensate for the dissymmetry of the vapor circulation flowing through a vapor duct 146.

In other embodiments, the bath of dielectric heat transfer fluid in liquid phase may be located exactly in the center of the immersion tank, therefore making the design of the immersion tank more symmetric. In such embodiments, all the condensers may be identical.

In the example embodiment shown in FIGS. 4, 5, 5A, and 6, the vapor duct 146 is formed by an upper portion 184 of the outer wall, and a vertical lateral portion of the outer wall 186. The vapor duct 146 may be at least as high as a width of the condenser 136. The divider plate 150 may form an essentially vertical barrier between the central zone 132, in which the bath of dielectric heat transfer fluid is located, and the one of the two distal zones 130, in which the condenser 136 is located. The divider plate 150 may be configured such that the upward path flow of vapor from the top surface of the dielectric fluid in liquid phase through the coils of the condenser 136 is hindered or prevented. The divider plate 150 can extend axially along the entire length of the immersion tank 120. The divider plate 150 extends vertically from a slanted lateral portion 188 of the outer wall of the immersion tank 120 to at least a level approximately as high as a top of the condenser 136. The top of the divider plate 150 is offset from the top of the immersion tank 120 by at least a width of the condenser 136. The condenser 136 can span a substantial portion of an entire length of the immersion tank 120. The condenser 136 is preferably disposed adjacent to the vertical lateral portion 174 of the outer wall of the immersion tank 120 so that there is little to no space between the vertical lateral portion 174 of the outer wall and the condenser 136 for the dielectric heat transfer fluid in vapor phase to pass. Similarly, the condenser 136 is preferably disposed adjacent to the divider plate 150, so that there is little to no space between the divider plate 150 and the condenser 136 for the dielectric heat transfer fluid in vapor phase to pass. The liquid funnel 176 is formed by the slanted lateral portion 188 of the outer wall, and a base portion 190 of the divider plate 150. The divider plate 150 may be vapor or liquid tight but for the one or more openings 156 provided in the base portion 190 of the divider plate 150. The one or more openings 156 are preferably equally distributed along the entire length of the immersion tank 120. The cumulated length of the one or more openings 156 may be approximately half of the entire length of the immersion tank 120 or more. The openings 156 have preferably a size sufficiently small to limit or entirely avoid inflow of dielectric heat transfer fluid in vapor phase into the liquid funnel 176, and sufficiently large to permit outflow of dielectric heat transfer fluid in vapor phase that has not condensed at the condenser 136. For example, the openings 156 have a size slightly (e.g., 10%) larger than the minimum size required to let the liquid condensed at the condenser 136 flow back to the bath of dielectric heat transfer fluid, using flow path 152 along the slanted lateral portion 188 of the outer wall of the immersion tank 120. In some embodiments, some of the openings 156 may be equipped with flappers (not shown) that further close the openings 156 when the flow of liquid condensate is low so that counterflow of vapor is further minimized or even prevented.

In some embodiments, the vapor duct 146 may include one or more high spot 148. The high spot 148 can be located at the top of the vapor duct 146. The high spot 148 may be formed by an upset of the upper portion 184 of the outer wall of the immersion tank 120. The high spot 148 may extend axially along the entire length of the immersion tank 120. The high spot 148 may be located above the condenser 136. The high spot 148 may be used to capture light gases that may otherwise foul the vapor of dielectric heat transfer fluid.

In other embodiments, the upper surface at the top of the condenser 136 may be slanted away from a horizontal surface, for example, the height of the upper surface at the top of the condenser 136 may decrease as a function of the distance from the central zone 132.

Without being limited by any working principle, when the immersion tank 120 is entirely filled with dielectric heat transfer fluid in liquid and vapor phases in thermodynamic equilibrium, the pressure in the immersion tank 120 and the temperature in the immersion tank 120 are related by the phase transition boundary of the phase diagram. In such case, when the pressure in the immersion tank 120 is allowed to vary, the immersion tank 120 can be operated at any pressure and temperature point that lies on the phase transition boundary of the phase diagram of the dielectric heat transfer fluid.

One or more aspects of the present disclosure are to control, and optionally optimize, the operating temperature of the liquid bath, broaden the operating range of a sealed immersion tank or vessel containing a particular fluid by changing the internal pressure in the immersion tank, and/or control the temperature of electric or electronics components immersed in the tank to maximize the component efficiency. Indeed, changing the internal pressure makes the dielectric fluid boil at a higher or lower temperature than the normal atmospheric boiling point of said dielectric fluid. Thus, the boiling point of a particular fluid can be adjusted upward or downward by changing the internal pressure in the sealed immersion tank, and the liquid bath can be operated within a broader range of temperatures. For instance, when using the 3M™ Novec™ 7100 Engineered Fluid, which has a boiling point of about 61° C. at atmospheric pressure, if the pressure in the immersion tank is maintained at about 19.3 psia (or 4.6 psig positive pressure), the boiling point of the 3M™ Novec™ 7100 Engineered Fluid would be adjusted to 69° C. when the liquid and vapor phases are in equilibrium. The adjustment of the boiling point may provide the target 69° C. liquid bath temperature, and may precisely control the temperature of the electric or electronics components to maximize efficiency. Alternatively, when using the 3M™ Novec™ 7200 Engineered Fluid, which has a boiling point of about 76° C. at atmospheric pressure, and if the pressure in the immersion tank is maintained at about 11.5 psia (or −3.2 psig vacuum), the boiling point of the 3M™ Novec™ 7200 Engineered Fluid would also be adjusted to 69° C. when the liquid and vapor phases are in equilibrium.

When the pressure in the immersion tank is maintained below atmospheric pressure, air would enter the tank, and little or no dielectric fluid vapor may exit the tank in cases of a small leakage through across the wall of the immersion tank. Thus, it may sometimes be preferable to maintain the pressure in the immersion tank below atmospheric pressure (e.g., below 14.7 psia) to avoid loss of dielectric fluid from the immersion tank.

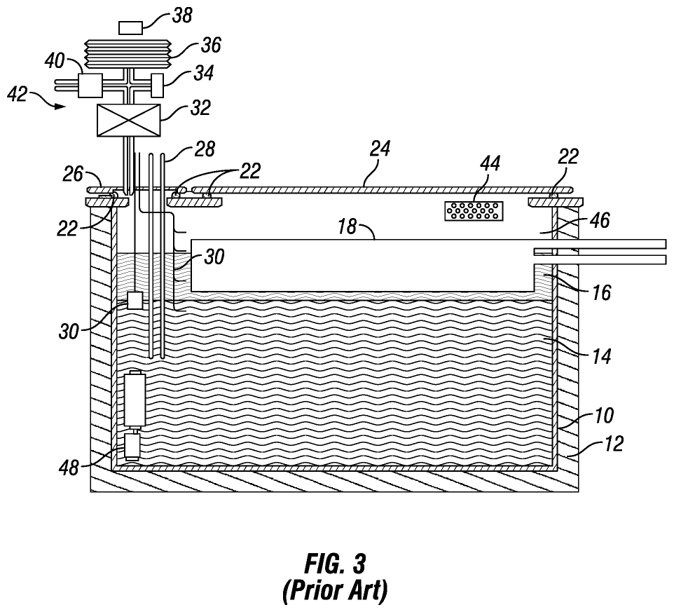

The immersion tank 120 described herein is preferably a sealed vessel in which pressure may vary. In contrast with the prior art example described in the background section, the immersion tank 120 is preferably devoid of the means for specifically maintaining atmospheric pressure. In particular, there is no bellows or other expansion device required by other prior art systems. The immersion tank 120 can be operated at a pressure lower than the atmospheric pressure when temperatures lower than the normal atmospheric boiling point of the dielectric fluid are desired for the liquid bath and electronic components. It is well known that the phase transition temperature of a liquid fluid decreases when the vapor pressure associated with that same fluid also decreases. Thus, the immersion tank 120 is preferably designed for operating in usual conditions with a vapor phase at a temperature lower (e.g., at least 5 deg. C lower) than the boiling temperature at atmospheric pressure of the dielectric heat transfer fluid. In particular, the condenser 136 is preferably configured or sized in a way such that it can transfer heat to the circulating fluid at the same rate or greater than heat is generated by the electric or electronic components, even when the vapor phase is at a temperature lower than the boiling temperature at atmospheric pressure of the dielectric heat transfer fluid. In other words, when the immersion tank 120 operating in usual conditions is at thermal equilibrium, the temperature in the immersion tank 120 can remain lower than the boiling temperature at atmospheric pressure of the dielectric heat transfer fluid. In contrast, the known two-phase immersion cooling system illustrated in FIGS. 1, 2 and 3 is only required to operate at usual conditions with a vapor phase at a temperature equal the boiling temperature at atmospheric pressure of the dielectric heat transfer fluid. Accordingly, compared to the known condenser 18 illustrated in FIG. 2, the condenser 136 can appear overdesigned.

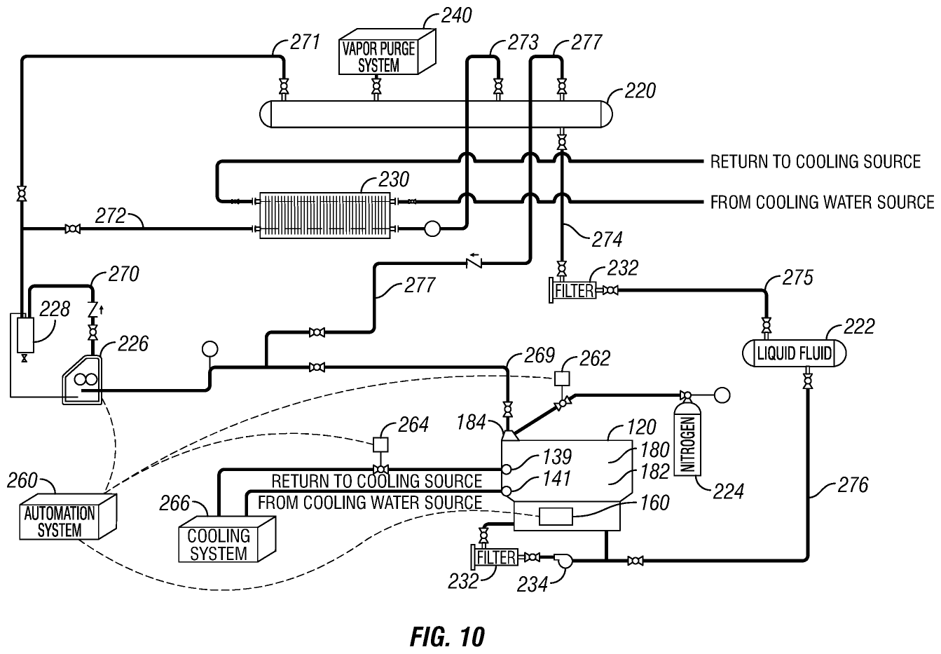

To facilitate management of liquid and vapor in the immersion tank 120 certain appurtenances are included in the immersion cooling system. These appurtenances are illustrated in FIG. 10.

When it becomes useful to remove vapor or other gas from the immersion tank 120, valve C is closed, then vacuum pump 226 is initiated and flow of the vapor or other gas is routed from upper portion 184 through line 269 and valve D. Flow leaves the vacuum pump 226 in line 270 through valve F and through a check valve into oil separator 228, retaining oil within the vapor flow and returning the oil to the vacuum pump 226. Valve E may be closed. Further vapor flow is routed through valve G and line 271 to the vapor holding tank 220, where the vapor can be stored until processing, if required.

To liquefy this vapor, valve D is closed, flow is initiated by the vacuum pump 226 and routed first in line 277 through valve C, and in line 270 through valve F. Valve G may be closed. Vapor is then routed through valve E in line 272, and through secondary condenser 230. The secondary condenser 230 exchanges heat between a cooling source of circulating fluid, and the vapor phase of the dielectric fluid. Due to the heat exchange within the secondary condenser 230, the dielectric fluid vapor changes, at least partially, to the liquid phase. The dielectric fluid returns to liquid state and then flows through line 273 to vapor holding tank 220, where the liquid phase settles by gravity. Optionally, the settled liquid phase may continue flowing via line 274 to liquid filter 232. Filtered liquid fluid leaves liquid filter 232 via line 275 to be held in liquid fluid tank 222 where the liquid fluid is stored. When additions of liquid fluid in the immersion tank 120 are useful, valve Y is opened, pump 234 is energized, and liquid fluid proceeds through line 276 into immersion tank 120 completing the cycle. During the process to remove condensable vapors, while the liquid that has settled by gravity in the vapor holding tank 22 may be returned to the immersion tank 120 via lines 274, 275, and 276, the vapor that did not turn to liquid in secondary condenser 230 may not settled by gravity can be recycled via line 277 through valve C and through vacuum pump 226, continuously cycling through secondary condenser 230 until it condenses into liquid.

Non-condensable vapors, and/or gas contaminants, may not settle by gravity even after several cycles through the secondary condenser 230 and may accumulate on top of the vapor holding tank 220. These non-condensable vapors and/or gas contaminants are removed from the immersion cooling system via vapor purge system 240.

In the normal course of operating the data center and any immersion tank 120, it may become useful to open the immersion tank 120 to physically access the electronic component board 160. In the process for opening the immersion tank 120, first the power to the electronic component board 160 is discontinued. As the temperature begins to decrease as a result of the change in electric energy dissipation, the pressure in the immersion tank 120 may decrease. At this time, valve 262 is opened to add nitrogen gas from nitrogen tank 224 to the immersion tank 120. The nitrogen gas is much lighter than the dielectric fluid vapor; therefore, the nitrogen gas and the dielectric fluid vapor may not mix, and the nitrogen gas may fill the top of the middle space 182 and the upper space 180. Thus, when any door or lid sealing the top of the immersion tank 120 is opened, only the nitrogen gas may escape to the atmosphere outside of the immersion tank 120. Once the doors or lids are returned to normal closed positions, the process of removing vapor or other gas is started as previously described. Nitrogen gas, being lighter than dielectric fluid vapor and closer to the inlet of line 269, is the first gas to be carried to the vapor holding tank 220. Also, when the process of liquefying the vapor is started, the nitrogen gas may not condense in secondary condenser 230, and may be returned to vapor holding tank 220, and may be removed to the vapor purge system 240, escaping for example to the atmosphere bearing along with it little to no dielectric fluid vapor.

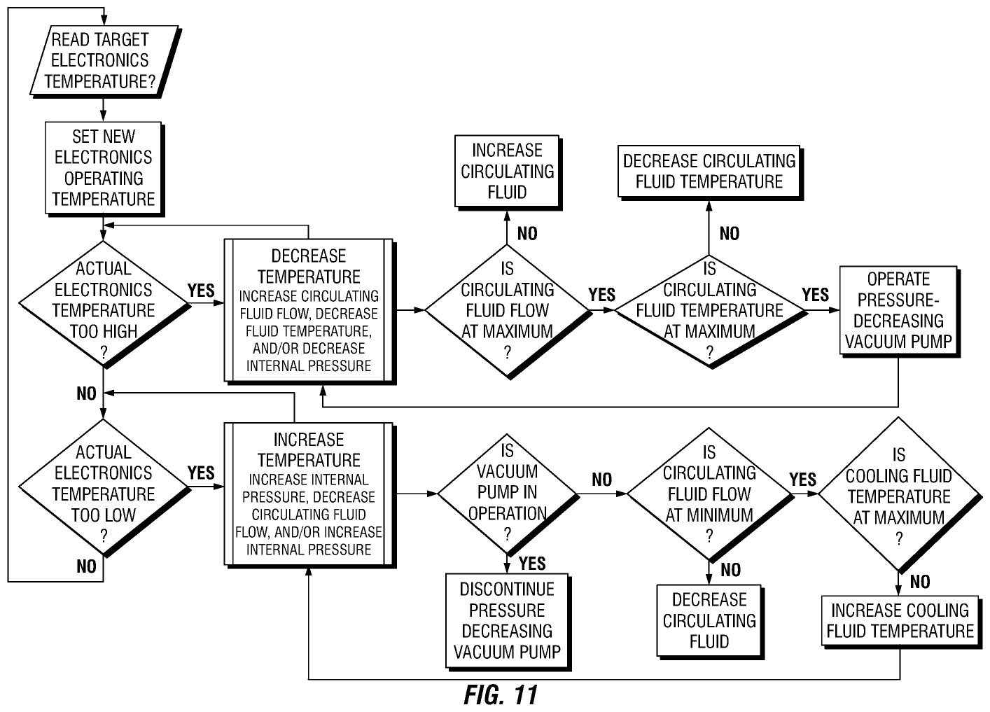

Turning to FIG. 11, a Process Flow Chart for operation of the two-phase immersion cooling system shown in FIG. 10 is illustrated. To control temperature, an automation system 260 receives a command from a human operator indicating the target temperature for the electronic components on board 160.

Note that receiving a command indicative of the target temperature of the electronic components on board 160 can be considered equivalent to receiving a command indicative of the target temperature for the liquid bath and/or an indication of the target temperature within the immersion tank 120. Indeed, while the temperature of the electronic components on board 160 may actually be different from the temperature of the liquid bath and/or the temperature within the immersion tank 120, these temperatures can be correlated. For example, the temperature of the liquid bath can be lower than the temperatures of the electronic components on board 160 by predetermined offsets, which can be measured. Thus, indicating a target temperature of one electronic component on board 160, or indicating a lower target temperature for the liquid bath may result in essentially the same control. The equivalence between commands may also hold when the relationships between the temperature of the liquid bath and the temperatures of the electronic components on board 160 are not predetermined offsets, but may vary in time.

The automation system 260 attempts to match the operating temperature of the components on component board 160 with the target temperature. A comparison is made between an indication of the current actual temperature of the electronic components on board 160 and the temperature to determine whether the current temperature within the immersion tank 120 is too either too high or too low. The liquid bath temperature and/or vapor temperature may be transmitted equivalently by a temperature sensor provided in the liquid bath and/or within the immersion tank.

If the actual temperature is found to be higher than the target temperature, then a control decision is made by the automation system 260 to handoff control to the Decrease Temperature Process. In the Decrease Temperature Process, first, a comparison is made between the maximum possible flow rate of the fluid circulating through distribution inlet 141, condenser 136, collection outlet 139, and a heat sink or cooling system 266, and the current actual flow rate of the fluid circulating. If the maximum possible flow rate has not been reached, then the circulating fluid flow rate is increased by operating valve 264 toward the open position. If the circulating fluid flow rate has already been maximized, or if it becomes maximized while performing the Decrease Temperature Process, then a decision to further decrease the temperature of the circulating fluid may optionally be made by the automation system 260, and sent to the cooling system 266, if a cooling system 266 is implemented. If after entering the Decrease Temperature Process it is determined that the circulating fluid flow rate is at maximum and the circulating fluid temperature is at the minimum possible, then vacuum pump 226 is operated to decrease the saturation pressure inside immersion tank 120 overall. This action of lowering the immersion tank pressure may lower the boiling point of the dielectric fluid contained in the immersion tank 120, which in turn may lower the operating temperature of the immersion tank 120 proportionally with the change in pressure, and lower the temperature of the electronic components on board 160.

If the actual temperature in the immersion tank 120 is found to be lower than the target temperature as set in the automation system 260, or as directed by the human operator, then a control decision is made to handoff control to the Increase Temperature Process. In the Increase Temperature Process, first, a comparison is made between the pressure inside immersion tank 120 and a maximum pressure. If the pressure is not at maximum, then operation of the vacuum pump 226 is discontinued. If the temperature requirement is not satisfied after the increase in pressure resulting from discontinuing operation of the vacuum pump 226, then a comparison is made between the current actual flow rate of the circulating fluid and the minimum possible flow rate of the fluid circulating. If the flow rate of circulating fluid is not at minimum, then the flow rate is decreased by modulating valve 264 toward the closed position. Then, if the temperature of the bath in immersion tank 120 is still below the target temperature, and the circulating fluid flow rate is at the minimum allowable, the circulating fluid temperature may optionally be further increased by the cooling system 266 until the temperature target is satisfied.

In other embodiments, vacuum pump 226 may be complemented with a compressor connected in parallel between the inlet of the vacuum pump 226 and the outlet of the check valve on line 270. The compressor may be used to flow dielectric vapor from the vapor holding tank 220 into the immersion tank 120. The compressor may also be equipped with an oil separator similar to oil separator 228. As such, the pressure inside the immersion tank 120 may be adjusted to a pressure that is either above or below atmospheric pressure.

In other embodiments, the vacuum pump 226 may be replaced by a pump that may be utilized bi-directionally, to flow dielectric vapor either from the immersion tank 120 to the vapor holding tank 220 or from the vapor holding tank 220 to the immersion tank 120.

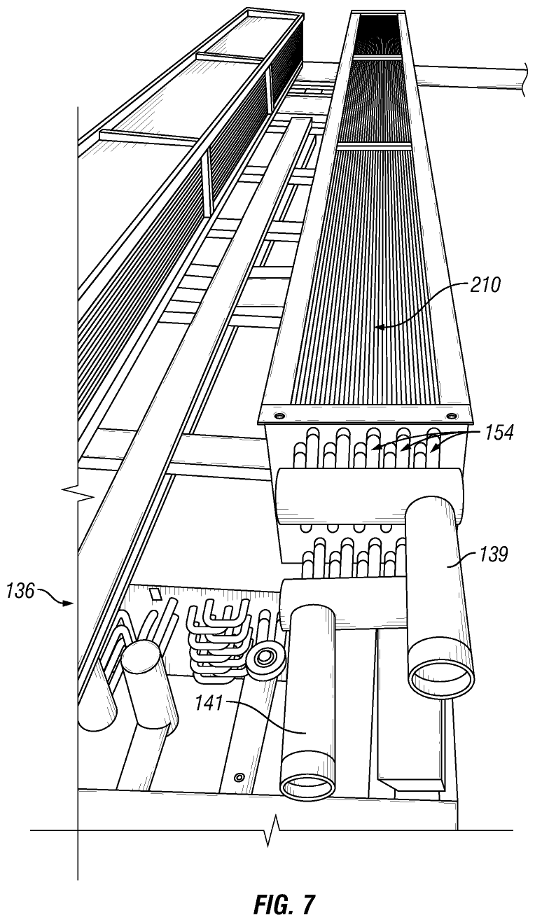

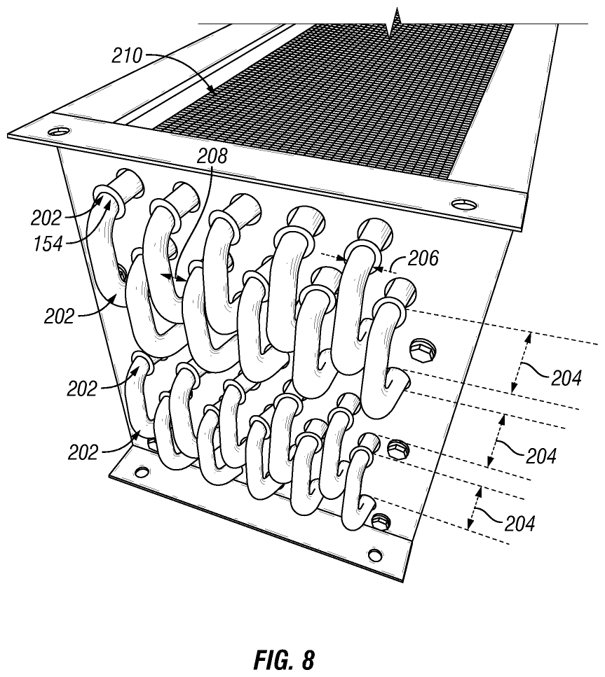

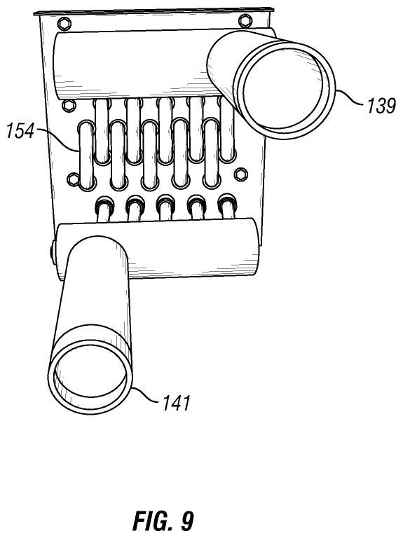

To increase the heat transfer capacity of the condenser 136 while keeping the size of the condenser 136 reasonably small, as well as achieving other objectives, the condenser 136 may be designed in accordance with one or more aspects of the condenser 136 illustrated in FIGS. 7, 8, and 9.

In the example embodiment shown in FIGS. 7, 8, and 9, the condenser 136 has a plurality of serpentine coils 154, each of the plurality of serpentine coils 154 including at least four, and preferably six horizontal passes 202. All of the plurality of serpentine coils 154 preferably have an inlet connected to a distribution inlet 141 of the condenser 136. The distribution inlet 141 is, in turn, connected to a source of relatively colder circulating fluid. All of the plurality of serpentine coils 154 preferably have an outlet connected to a collection outlet 139 of the condenser 136. The collection outlet 139 is, in turn, connected to a discharge of relatively warmer circulating fluid.

For example, each of the plurality of serpentine coils 154 have passes 202 that can be distributed vertically. Consecutive passes 202 of any of the plurality of serpentine coils 154 can be separated by a first distance 204 that is approximately equal to two times the diameter 206 of the coils. Serpentine coils 154 that are adjacent can be distributed horizontally vis-a-vis one another, for example, staggered, and/or separated by a second distance 208 that is less than the diameter 206 of the coils.

A plurality of transverse fins 210 may be coupled to any of the plurality of serpentine coils 154. The transverse fins 210 increase the area on which the dielectric heat transfer fluid can condense. For example, all of the plurality of plurality of transverse fins 210 can be disposed vertically, essentially perpendicularly to any of the plurality of serpentine coils 154. Any of the plurality of transverse fins 210 can be coupled to all of the serpentine coils 154. The transverse fins 210 preferably span essentially an entire height of the condenser 136. In contrast with enhanced tubes illustrated in FIG. 2, the dielectric heat transfer fluid can flow down along a surface of the transverse fins 210 without having to form a liquid drop in vapor, which may be advantageous when dielectric heat transfer fluid has a high internal cohesion and/or high adhesion with the materials making the condenser 136. Thus, the transverse fins 210 can be used for limiting the thickness of the film of dielectric heat transfer fluid that has condensed on the serpentine coils 154 and/or the transverse fins 210.

In some embodiments, an immersion tank for a two-phase immersion cooling system having a capacity of at least one hundred kilo-Watts may comprise one or more condenser. The one or more condenser may include a plurality of serpentine coils and a plurality of transverse fins that span essentially over an entire height of the one or more condenser.

While the disclosure is susceptible to various modifications and alternative forms, specific embodiments thereof are shown by way of example in the drawings and description. It should be understood, however, that the drawings and detailed description thereto are not intended to limit the claims to the particular form disclosed, but on the contrary, the intention is to cover all modifications, equivalents, and alternatives falling within the scope of the claims.

What is claimed is:

1. A two-phase immersion cooling system, comprising:
an immersion tank including a container for holding a bath of dielectric heat transfer fluid in liquid phase and at least one condenser for condensing dielectric heat transfer fluid from a vapor phase to a liquid phase; and
a means of selectively adjusting a pressure inside the immersion tank.

2. The two-phase immersion cooling system of claim 1 wherein the means of selectively adjusting the pressure inside the immersion tank comprises a vacuum pump to reduce the pressure below atmospheric pressure.

3. The two-phase immersion cooling system of claim 2 wherein the means of selectively adjusting the pressure inside the immersion tank further comprises a compressor to increase the pressure above atmospheric pressure.

4. The two-phase immersion cooling system of claim 1 further comprising:
a valve configured to vary a flow rate of a fluid circulating through the at least one condenser; and
an automation system programmed to actuate the valve based on an actual temperature measured inside the immersion tank and a target temperature.

5. The two-phase immersion cooling system of claim 4 further comprising an electric component having a temperature sensor, and wherein the actual temperature inside the immersion tank is measured by the temperature sensor.

6. The two-phase immersion cooling system of claim 5 wherein the fluid circulating through the at least one condenser is water or essentially water.

7. The two-phase immersion cooling system of claim 1 further comprising:
a cooling system configured to vary a temperature of a fluid circulating through the at least one condenser; and
an automation system programmed to control the cooling system based on an actual temperature measured inside the immersion tank and a target temperature.

8. The two-phase immersion cooling system of claim 7 further comprising an electric component having a temperature sensor, and wherein the actual temperature inside the immersion tank is measured by the temperature sensor.

9. The two-phase immersion cooling system of claim 1 further comprising an automation system programmed to adjust the pressure inside the immersion tank based upon an actual temperature measured inside the immersion tank and a target temperature.

10. The two-phase immersion cooling system of claim 9 further comprising an electric component having a temperature sensor, and wherein the actual temperature inside the immersion tank is measured by the temperature sensor.

11. The two-phase immersion cooling system of claim 1 further comprising an external storage tank, wherein the means of selectively adjusting the pressure inside the immersion tank is connected between the immersion tank and the external storage tank.

12. The two-phase immersion cooling system of claim 11 further comprising means for liquefying dielectric heat transfer fluid in vapor phase that is contained in the external storage tank.

13. The two-phase immersion cooling system of claim 12 further comprising means for pumping into the immersion tank dielectric heat transfer fluid in liquid phase that is contained in the external storage tank.

14. A two-phase immersion cooling system, comprising:
an immersion tank including a container for holding a bath of dielectric heat transfer fluid in liquid phase and at least one condenser for condensing dielectric heat transfer fluid from a vapor phase to a liquid phase; and
a vacuum pump located external to the immersion tank and configured to reduce a pressure inside the immersion tank below atmospheric pressure.

15. The two-phase immersion cooling system of claim 14 further comprising a secondary condenser, wherein a vacuum pump exhaust is connected to the secondary condenser.

16. The two-phase immersion cooling system of claim 15 further comprising an external storage tank, wherein the secondary condenser is connected to an inlet of an external storage tank and wherein an outlet of the external storage tank is connected to the immersion tank.

17. The two-phase immersion cooling system of claim 14 further comprising an automation system programmed to adjust the pressure inside the immersion tank based upon an actual temperature measured inside the immersion tank and a target temperature.

18. The two-phase immersion cooling system of claim 17 further comprising an electric component having a temperature sensor, and wherein the actual temperature inside the immersion tank is measured by the temperature sensor.

19. A two-phase immersion cooling system, comprising:
an immersion tank including a container for holding a bath of dielectric heat transfer fluid in liquid phase and at least one condenser for condensing dielectric heat transfer fluid from a vapor phase to a liquid phase; and
a valve configured to vary a flow rate of a fluid circulating through the at least one condenser or a cooling system configured to vary a temperature of the fluid circulating through the at least one condenser; and
an automation system programmed to actuate the valve or the cooling system based on an actual temperature measured inside the immersion tank and a target temperature.

20. The two-phase immersion cooling system of claim 19 further comprising an electric component having a temperature sensor, and wherein the actual temperature inside the immersion tank is measured by the temperature sensor.
